(19) United States
(12) Patent Application Publication
(10) Pub. No.: US 2013/0043067 A1
(43) Pub. Date: Feb. 21, 2013

(54) Wire Substrate Structure

(71) Applicant: Katsura HAYASHI, Kirishima-shi (JP)

(72) Inventor: Katsura HAYASHI, Kirishima-shi (JP)

(73) Assignee: KYOCERA CORPORATION, Kyoto-shi (JP)

(21) Appl. No.: 13/350,487

(22) Filed: Jan. 13, 2012

Related U.S. Application Data
(60) Provisional application No. 61/524,685, filed on Aug. 17, 2011.

(51) Int. Cl. H05K 1/00; B32B 5/16; B82Y 99/00

(52) U.S. Cl. 174/258; 428/323; 977/932

(57) ABSTRACT

[PROBLEM] To provide a circuit board improved in electrical reliability.

[SOLUTION] A circuit board 3 comprises a plurality of first inorganic insulating particles 13a which are connected to each other via first neck structures 17a and have a particle size of 3 nm or more and 110 nm or less and a resin (third filling portions 19c) arranged in first gaps G1 among the plurality of first inorganic insulating particles 13a.

### TECHNICAL FIELD

The present invention relates to a structure which is used in all sorts of items such as electronic equipment (for example various types of audio-visual equipment, household electrical appliances, telecommunication equipment, and computer equipment and their peripherals), transport machinery, buildings or the like and to a circuit board which is used in electronic equipment.

### BACKGROUND ART

Conventionally, as a circuit board which is used in electronic equipment, a circuit board provided with a resin layer and a ceramic layer is known.

For example, the patent literature 1 discloses a circuit board formed by thermally spraying ceramic to one surface of metal foil to form a ceramic layer, stacking a prepreg so as to contact the ceramic layer side of the metal foil, and hot pressing the same.

### CITATION LIST

### Patent Literature

Patent Literature 1: Japanese Patent Publication (A) No. 2-253941

### SUMMARY OF INVENTION

### Technical Problem

However, in general, a ceramic layer has a high rigidity, but easily cracks. Therefore, when the circuit board is subjected to stress, a crack is easily caused in the ceramic layer. Therefore; when the crack extends and reaches an line, the line is easily broken and consequently the circuit board easily falls in electrical reliability.

Accordingly, it has been desired to provide a structure and a circuit beard improved in electrical reliability.

### Solution to Problem

A structure according to one aspect of the present invention comprises a plurality of first inorganic insulating particles which are connected to each other via first neck structures and have a particle size of 3 nm or more and 110 nm or less, and a resin arranged in gaps among the plurality of first inorganic insulating particles.

A circuit board according to one aspect of the present invention comprises an inorganic insulating layer having a plurality of first inorganic insulating particles which are connected to each other via first neck structures and have a particle size of 3 nm or more and 110 nm or less, and a resin arranged in gaps among the plurality of the first inorganic insulating particles.

### Advantageous Effects of Invention

According to the above-described configuration, the electrical reliability can be improved.

### BRIEF DESCRIPTION OF DRAWINGS

FIG. 1 is a cross-sectional view cutting a mounting structure provided with a circuit board according to an embodiment of the present invention in a thickness direction.

FIG. 2A is a cross-sectional view showing enlarged an R1 portion of the mounting structure shown in FIG. 1, while FIG. 28 is a cross-sectional view showing enlarged an R2 portion of the mounting structure shown in FIG. 1.

FIG. 3A is a cross-sectional view cut in a plane direction along the IIIa-IIIa line in FIG. 28, while FIG. 3B is a cross-sectional view showing enlarged an R3 portion of the mounting structure shown in FIG. 2A.

FIG. 4A to FIG. 4F are cross-sectional views cut in a thickness direction which explain steps of production of the circuit board shown in FIG. 1.

FIG. 5A to FIG. 5C are cross-sectional views cut in a thickness direction which explain steps of production of the circuit board shown in FIG. 1.

FIG. 6A and FIG. 6B are cross-sectional views cut in a thickness direction which explain steps of production of the circuit board shown in FIG. 1.

FIG. 7 is a photograph which captures a portion of a cross-section of a laminate according to an example by a transmission electron microscope.

FIG. 8A is a photograph enlarging an R5 portion in FIG. 7, and FIG. 8B is a photograph enlarging an R6 portion in FIG. 8A.

### DESCRIPTION OF EMBODIMENTS

Below, a circuit board according to an embodiment of the present invention will be explained in detail based on the drawings.

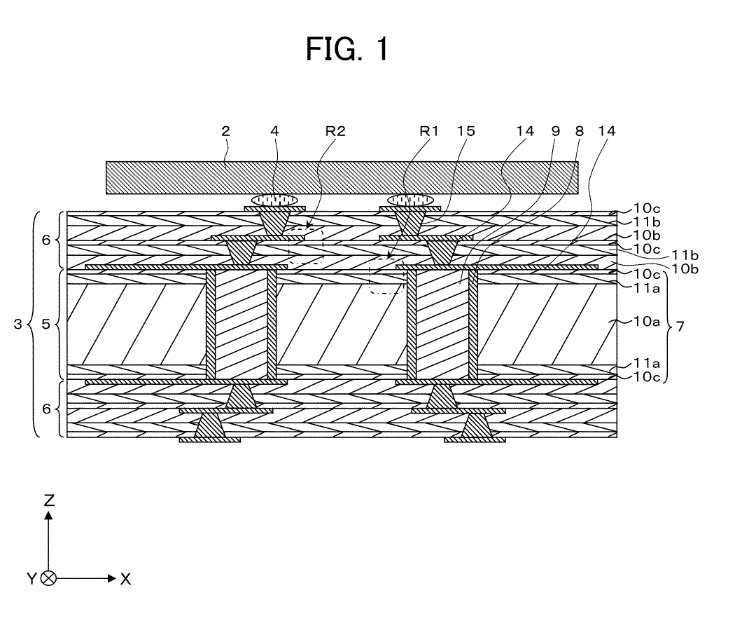

A circuit hoard 3 shown in FIG. 1 is used in for example an electronic equipment such as various types of audio-visual equipment, household electrical appliances, telecommunication equipment, computer equipment their peripherals, or the like.

This circuit board 3 includes a core board 5 and a pair of circuit layers 6 formed on the top and bottom surfaces of the core board 5. It has the functions of supporting an electronic component 2 and supplying electrical power or signals to the electronic component 2 for driving or controlling the electronic component 2.

Note that, the electronic component 2 is for example a semiconductor device such as an IC, LSI or the like and is flip-chip mounted on the circuit board 3 with bumps 4 made of conductive material such as solder or the like. In this electronic component 2, the base material is formed by for example semiconductor material such as silicon, germanium, gallium arsenide, gallium, arsenide phosphide, gallium nitride, silicon carbide, or the like.

Below, the configuration of the circuit board 3 will be explained in detail.

(Core Board)

The core board 5 raises the rigidity of the circuit board 3 while facilitating conduction between the pair of circuit layers 6 and includes a base substrate 7 which supports the circuit layers 6, through-holes which are provided in the base substrate 7, cylindrical through-hole conductors 8 which are provided in the through-holes and electrically connect the pair of circuit layers 6 to each other, and insulators 9 which are surrounded by the through-hole conductors 8.

The base substrate 7 has a first resin layer 10a, first inorganic insulating layers 11a provided on the top and bottom surfaces of the first resin layer 10a, and third resin layers 10c provided on one major surfaces of the first inorganic insulating layers 11a so as to be arranged at the outermost layers of the base substrate 7.

The first resin layer 10a forms a principal part of the base substrate 7 and for example includes a resin portion and a base material covered on the resin portion. The first resin layer 10a is set in thickness to for example 0.1 mm or more and 3.0 mm or less, set in Young's modulus to for example 0.2 GPa or more and 20 GPa or less, set in thermal expansion coefficient in the plane direction to for example 3 ppm/° C. or more and 20 ppm/° C. or less, set in thermal expansion coefficient in the thickness direction to for example 30 ppm/° C. or more and 50 ppm/° C. or less, and set in dielectric tangent to for example 0.01 or more and 0.02 or less.

Here, the Young's modulus of the first resin layer 10a is measured by using a commercially available tensile tester by a measurement method according to ISO527-1: 1993. Further, the thermal expansion coefficient of the first resin layer 10a is measured by using a commercially available TMA (Thermo-Mechanical Analysis) device by a measurement method according to JIS K7197-1991. Further, the dielectric tangent of the first resin layer 10a is measured by a resonator method according to JIS R1627-1996. Below, the thermal expansion coefficients and dielectric tangents of members commencing with second and third resin layers 10b and 10c and first and second inorganic insulating layers 11a and 11b are measured in the same way as the first resin layer 10a.

The resin portion of the first resin layer 10a can be formed by for example a heat curing resin such as an epoxy resin, bismaleimide triazine resin, cyanate resin, polyphenylene ether resin, fully aromatic polyamide resin polyimide resin, or the like. The resin portion is set in Young's modulus to for example 0.1 GPa or more and 5 GPa or less and set in thermal expansion coefficients in the thickness direction and plane direction to for example 20 ppm/° C. or more and 50 ppm/° C. or less.

Here, the Young's modulus and hardness of the first resin layer 10a are measured by the following method according to ISO14577-1:2002. First, the resin portion of the first resin layer 10a is cut along the thickness direction, then the cut surface is polished by argon ions. Next, by using a nano-indenter, a load is applied to a Berkovich indenter made of diamond of the nano-indenter so as to push the indenter against the polished surface. Next, the load applied to the pushed indenter is divided by the contact projection area to thereby calculate the hardness. Further, from the relationship between the load and the pushing depth when pushing, a load-displacement curve is found, and from the load-displacement curve, the Young's modulus is calculated. In this measurement, for example, a nano-indenter XP made by MTS Systems Cooperation can be used. Below, the Young's moduli and hardnesses of the embers commencing with the second and third resin layers 10b and 10c, first and second inorganic insulating layers 11a and 11b, and first and second inorganic insulating particles 13a and 13b are measured in the same way as the resin portion of the first resin layer 10a.

The base material included in the first resin layer 10a reduces the thermal expansion coefficient in the plane direction of the first resin layer 10a and raises the rigidity of the first resin layer 10a. The base material, for example, can be formed by a woven fabric or non-woven fabric comprised of a plurality of fibers or by a fiber group comprised of a plurality of fibers arranged in one direction. As the fiber, for example, glass fiber; resin fiber, carbon fiber, metal fiber, or the like can be used.

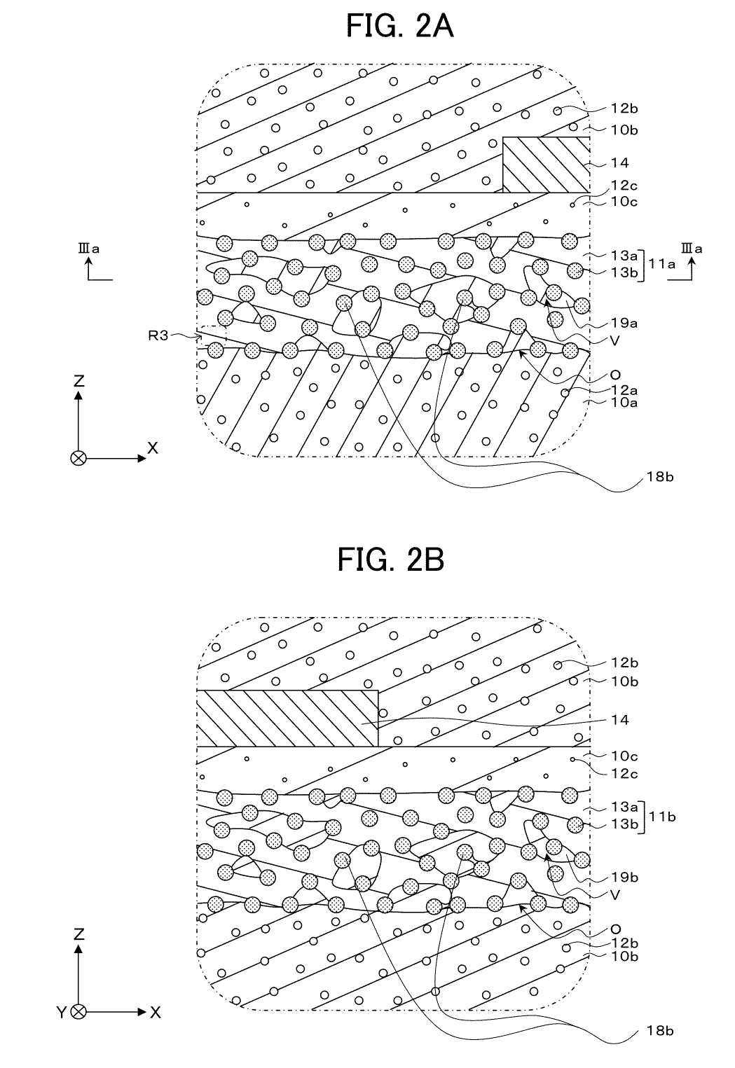

The first resin layer 10a, further, as shown in FIG. 2A, includes a first filler 12a comprised of many first filler particles formed by an inorganic insulating material. As a result, the thermal expansion coefficient of the first resin layer 10a can be reduced, and the rigidity of the first resin layer 10a can be raised. The first filler particles can be formed by for example inorganic insulating material such as silicon oxide, aluminum oxide, aluminum nitride, aluminum hydroxide, calcium carbonate, or the like. The first filler particles are set, in particle size to for example 0.5 μm or more and 5.0 μm or less and set in thermal expansion coefficient to for example 0 ppm/° C. or more and 15 ppm/° C. or less. Further, the ratio of volume of the first filler 12a relative to a sum of volumes of the resin portion of the first resin layer 10a and the first filler 12a (hereinafter, referred to as the “content of the first filler 12a”) is set to for example 3 vol % or more and 60 vol % or less.

Here, the particle size of the first filler particles is measured as follows. First, the polished surface or fractured surface of the first resin layer 10a is observed by a field emission type electron microscope, and a cross-section magnified so as to include 20 or more to 50 or less particles is photographed. Next, at the magnified cross-section, the maximum diameter of each particle is measured, then the measured, maximum particle size is determined as the particle size of the first filler particle. Further, the content (vol %) of the first filler 12a is measured by photographing polished surfaces of the first resin layer 10a by a field emission type electron microscope, using an image analyzer or the like to measure the area ratio (area %) of the first filler 12a occupied in the resin portion of the first resin layer 10a on the cross-sections of 10 spots, and calculating a mean value of the measured values and regarding it as the content (vol %).

On the other hand, the first inorganic insulating layers 11a formed on the top and bottom surfaces of the first resin layer 10a are comprised of inorganic insulating material such as for example silicon oxide, aluminum oxide, boron oxide, magnesium oxide, calcium oxide, or the like. Compared with the resin material, they are high in rigidity, therefore have the function of raising the rigidity of the base substrate 7.

The thermal expansion coefficient in the plane direction of the first inorganic insulating layers 11a is low compared with thermal expansion coefficients in the plane direction of general resin materials. Therefore, the thermal expansion coefficient in the plane direction of the circuit board 3 can be made close to the thermal expansion coefficient in the plane direction of the electronic component 2, and warping of the circuit board 3 caused by thermal stress can be reduced.

The thermal expansion coefficient in the thickness direction of the first inorganic insulating layers 11a is smaller than the thermal expansion coefficient in the thickness direction of a resin film which is low in thermal expansion coefficient in the plane direction. Therefore, compared with the case where a resin film is used, the thermal expansion coefficient in the thickness direction of the base substrate 7 can be reduced, the thermal stress caused by a difference of thermal expansion coefficient between the base substrate 7 and the through-hole conductor 8 is made smaller, and disconnection of the through-hole conductors 8 can be reduced.

In general, an inorganic insulating material is lower in dielectric tangent than a resin material. In addition, the first inorganic insulating layers 11a are arranged closer to the circuit layers 6 than the first resin layer 10a. Therefore, due to the first inorganic insulating layers 11a, the signal transmission characteristics of the circuit layers 6 arranged on the top and bottom surfaces of the core board 5 are raised.

The thickness of the first inorganic insulating layers 11a is set to for example 3 μm or more and 100 μm or less and/or 3% or more and 10% or less the first resin layer 10a. Further, the Young's modulus of the first inorganic insulating layers 11a is set to for example 10 GPa or more and 100 GPa or less and/oar 10 times or more and 100 times or less the first resin layer 10a. Further, the first inorganic insulating layers 11a are set in thermal expansion coefficients in the thickness direction and plane direction to for example 0 ppm/° C. or more and 10 ppm/° C. or less and are set it dielectric tangent to for example 0.0001 or more and 0.001 or less.

These first inorganic insulating layers 11a can be formed by the above-explained inorganic insulating material. Among them, from the viewpoint of low dielectric tangent and low thermal expansion coefficient, use of silicon oxide is desirable.

Further, the first inorganic insulating layers 11a are formed by an inorganic insulating material in an amorphous state. An amorphous-state inorganic insulating material, compared with a crystal-state inorganic insulating material, can reduce anisotropy of the thermal expansion coefficient caused by the crystal structure. Therefore, after heating of the circuit board 3, when the circuit board 3 is cooled, shrinkage of the first inorganic insulating layers 11a can be made more uniform in the thickness direction and plane direction, and generation of cracks in the first inorganic insulating layers 11a can be reduced.

As this amorphous-state inorganic insulating material, for example, inorganic insulating materials containing silicon oxide to 90 mass % or more can be used. Among them, use of an inorganic insulating material containing silicon oxide to 99 mass % or more and less than 100 mass % is desirable. When an inorganic insulating material containing silicon oxide to 90 mass % or more and less than 100 mass % is used, the inorganic insulating material may include, other than the silicon oxide, for example, aluminum oxide, titanium oxide, magnesium oxide, zirconium oxide, or another insulating material as well. Note that, the inorganic insulating material in the amorphous state is set in region of crystal phase to for example less than 10 vol %. Among them, setting to less than 5 vol % is desirable.

Here, the volume ratio of the crystal phase region of the silicon oxide is measured as follows. First, a plurality of comparative samples containing 100% crystallized sample powder and amorphous powder in different ratios are manufactured. The comparative samples are measured by the X-ray diffraction method to thereby prepare a calibration curve showing a relative relationship between the measured values and the volume ratio of the crystal phase region. Next, the examination samples being measured are measured by the X-ray diffraction method. Each measured value and the calibration curve are compared, and the volume ratio of the crystal phase region is calculated from the measured value, whereby the volume ratio of the crystal phase region of aj examination sample is measured.

The above-explained first inorganic insulating layers 11a, as shown in FIG. 2A, include a plurality of first inorganic insulating particles 13a and a plurality of second inorganic insulating particles 13b having a larger particle size than the first inorganic insulating particles 13a. These first inorganic insulating particles 13a and second inorganic insulating particles 13b can be formed by insulating material such as for example the above-explained silicon oxide, aluminum oxide, boron oxide, magnesium oxide, calcium oxide, or the like.

Further, the first and second inorganic insulating layers 11a and 11b contain the first inorganic insulating particles 13a in 20 vol % or more and 40 vol % or leas with respect to the total volume of the first inorganic insulating particles 13a and second inorganic insulating particles 13b and contain the second inorganic insulating particles 13b in 60 vol % or more and 80 vol % or less with respect to the total volume. By increase of the second inorganic insulating particles 13b to a certain extent in this way, in regions among a plurality of second inorganic insulating particles 13b, voids V which, will be explained later can be easily formed.

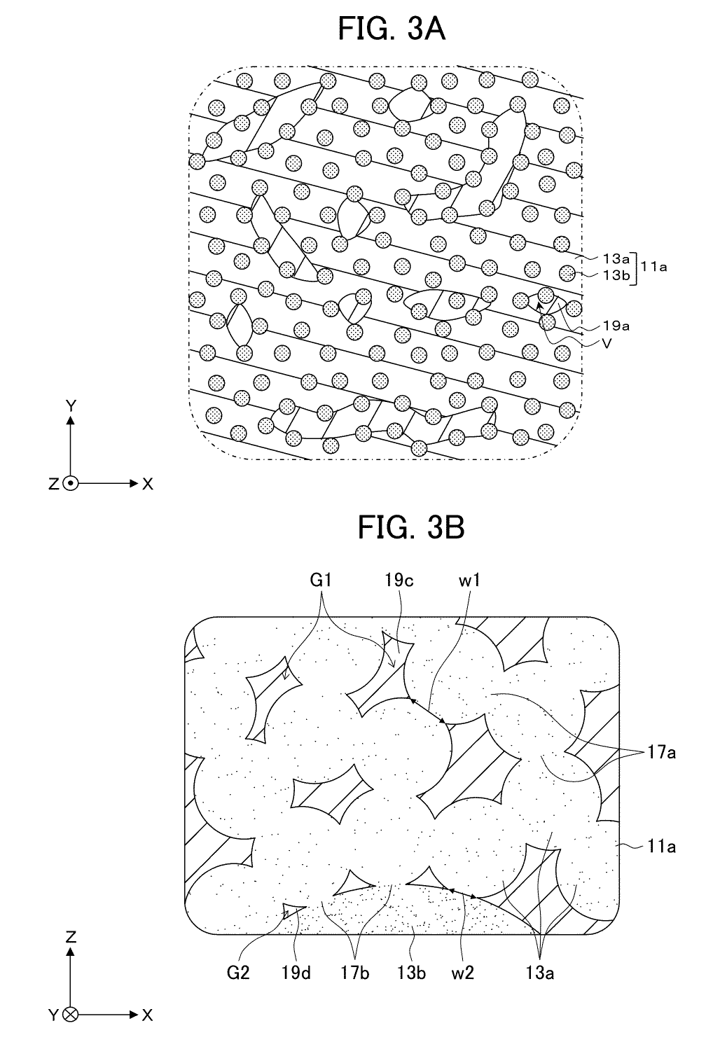

The first inorganic insulating particles 13a are set in particle size to 3 nm or more and 110 nm or less. As shown in FIG. 3B, they are connected to each other with the first neck structures 17a interposed therebetween. Due to this, in the first inorganic insulating layers 11a, compared with a resin in which a filler is mixed, inorganic insulating particles are minutely arranged. Further, the first inorganic insulating particles 13a are connected to each other to exhibit a frame structure. The individual first inorganic insulating particles 13a constrain each other and are hard to flow. Therefore, compared with a resin in which a filler is dispersed, a low thermal expansion coefficient and high rigidity inorganic insulating layer can be obtained. Note that, the Young's modulus of the first inorganic insulating particles 13a is set to for example 10 GPa or more and 30 GPa or less, and the hardness of the first inorganic insulating particles 13a is set to for example 0.5 GPa or more and 2 GPa or less.

Further, the second inorganic insulating particles 13b are set in particle size to 0.5 μm or more and 5 μm or less and are connected with the first inorganic insulating particles 13a by second neck structures 17b interposed therebetween, thereby to be bonded to each other with the first inorganic insulating particles 13a interposed therebetween. Note that, the particle size of the second inorganic insulating particles 13b is set to for example 10 times or more and 200 times or less the particle size of the first inorganic insulating particles 13a. Further, the Young's modulus of the second inorganic insulating particles 13b is set to for example 40 GPa or more and 75 GPa or less and/or set to for example 2 times or more and 7 times or less the Young's modulus of the first inorganic insulating particles 13a. Further, the hardness of the second inorganic insulating particles 13b is set to for example 5 GPa or more and 10 GPa or less and/or set to for example 3 times or more and 20 times or less the hardness of the first inorganic insulating particles 13a.

Here, the first inorganic insulating particles 13a and second inorganic insulating particles 13b are confirmed by observing a polished surface or fractured surface of a first inorganic insulating layer 11a by a field emission type electron microscope. Further, the vol % of the first inorganic insulating particles 13a and second inorganic insulating particles 13b are calculated as follows. First, a polished surface of a first inorganic insulating layer 11a is photographed by a field emission type electron microscope. Next, from the photographed image, by using an image analyzer or the like, the area ratio (area %) of the first inorganic insulating particles 13a and second inorganic insulating particles 13b is measured. Then, by calculating the mean value of the measured values, the vol % of the first and second inorganic insulating particles 13a and 13b are calculated. Further, the particle sizes of the first inorganic insulating particles 13a and second inorganic insulating particles 13b are measured by observing a polished surface or fractured surface of a first inorganic insulating layer 11a by a field emission type electron microscope, photographing the cross-section magnified so as to include 20 or more particles, but 50 or less particles, and measuring the maximum diameter of the particles on the photographed magnified cross-section.

The third resin layers 10c are interposed between the first inorganic insulating layers 11a and conductive layers 14 which will be explained later and have a function of easing the thermal is tress between the first inorganic insulating layers 11a and the conductive layers 14 and a function of reducing disconnection of the conductive layers 14 caused by cracks of the first inorganic insulating layers 11a. They abut at one major surfaces against the first inorganic insulating layers 11a and abut at the other major surfaces against the conductive layers 14 and for example include resin portions and third fillers 12c covered on the resin portion.

Further, the third resin layers 10c are set in thickness to for example 0.1 μm or more and 5 μm or less, set in Young's modulus to for example 0.01 GPa or more and 1 GPa or less, set in hardness to for example 0.01 GPa or more and 0.3 GPa or less, set in thermal expansion coefficients in the thickness direction and plane direction to for example 20 ppm/° C. or more and 100 ppm/° C. or less, and set in dielectric tangent to for example 0.005 or more and 0.02 or less.

The third resin layers 10c are preferably set in thickness smaller and set in Young's modulus lower compared with the first resin layer 10a, second resin layer 10b, and first and second inorganic insulating layers 11a and 11b. In this case, due to the third resin layers 10c, which are thin and easily elastically deformed, the thermal stress caused by the difference of the thermal expansion coefficient between the first and second inorganic insulating layers 11a and 11b and the conductive layers 14 is eased. Accordingly, separation of the conductive layers 14 from the first and second inorganic insulating layers 11a and 11b is suppressed, disconnection of the conductive layers 14 can be reduced, and consequently it becomes possible to obtain a circuit board 3 excellent in electrical reliability.

The resin portion included in the third resin layers 10c forms the principal part of the third resin layers 10c and is made of for example a heat curing resin such as epoxy resin, bismaleimide triazine resin, cyanate resin, polyphenylene ether resin, fully aromatic polyamide resin, polyimide resin, or the like.

The third filler 12c included in the third resin layers 10c has a function of raising flame retardance of the third resin layers 10c and a function of keeping stacked sheets from sticking with each other at the time of handling as will be explained later and is comprised of many third filler particles formed by inorganic insulating material such as for example silicon oxide or the like. This third filler particles are set in particle size to for example 0.05 μm or more and 0.7 μm or less and set in content in the third resin layers 10c to for example 0 vol % or more and 10 vol % or less. Note that, the particle size and content of the third filler particles are measured in the same way as the first filler particles.

Further, in the base substrate 7, columnar shaped through-holes which penetrate through the base substrate 7 in the thickness direction and have diameters of for example 0.1 mm or more and 1 mm or less are provided. Inside each through-hole, a through-hole conductor 8 which electrically connects the top and bottom circuit layers 6 of the core board 5 is formed in a cylindrical shape along the inner wall of the through-hole. This through-hole conductor 8 can be formed by conductive material such as for example copper, silver, gold, aluminum, nickel, chromium, or the like and is set in thermal expansion, coefficient to for example 14 ppm/° C. or more and 18 ppm/° C. or less.

In a hollow portion of each cylindrically formed through-hole Conductor 8, an insulator 9 is formed in a columnar shape. The insulator 9 can be formed by for example resin material such as polyimide resin, acryl resin, epoxy resin, cyanate resin, fluorine resin, silicone resin, polyphenylene ether resin, bismaleimide triazine resin, or the like.

(Circuit Layer)

On the other hand, on the top and bottom surfaces of the core board 5, as explained above, a pair of circuit layers 6 are formed.

Between the pair of circuit layers 6, one circuit layer 6 is connected with respect to the electronic component 2 by the bumps 4 interposed therebetween, while the other circuit layer 6 is connected to a not shown external circuit board by a not shown bonding material interposed therebetween.

Each circuit layer 6 has a conductive layer 14 which is partially formed on the third resin layer 10c of the core board 5. On the top of that, it has one or more combinations of sequentially a laminated second resin layer 10b, second inorganic insulating layer 11b, third resin layer 10c, and conductive layer 14. Further, each circuit layer 6 includes a plurality of via holes penetrating through the second resin layer 10b, second inorganic insulating layer 11b, and third resin layer 10c and a plurality of via conductors 15 formed in the via holes. Further, the conductive layer 14 and via conductors 15 are electrically connected to each other and configure a ground-use line, power-use line, and/or signal-use lines.

A plurality of conductive layers 14 are formed on each third resin layer 10c and are spaced in the thickness direction from each other by the second resin layer 10b, second inorganic insulating layer 11b, and third resin layer 10c interposed therebetween. The conductive layers 14 can be formed by conductive material such as for example copper, silver, gold, aluminum, nickel, chromium, or the like. Further, the conductive layers 14 are set in thickness to 3 μm or more and 20 μm or less and set in thermal expansion coefficient to for example 14 ppm/° C. or more and 18 ppm/° C. or less.

The second resin layer 10b abuts against the side surfaces and major surfaces of the conductive layers 14 and functions as an insulating member preventing short-circuiting between the conductive layers 14 which are spaced from each other along the thickness direction or plane direction. The second resin layer 10b can be formed by for example heat curing resin such as an epoxy resin, bismaleimide triazine resin, cyanate resin, polyphenylene ether resin, fully aromatic polyamide resin or polyimide resin, or the like.

The thickness of the second resin layer 10b is set to for example 3 μm or more and 30 μm of less and/or set to for example 1.5 times or more and 20 times or less the thickness of the third, resin layer 10c. Further, the Young's modulus of the second resin layer 10b is set to for example 0.2 GPa or more and 20 GPa or less and/or set to for example 2 times or more and 100 times or less the Young's modulus of the third resin layer 10c. Further, the hardness of the second resin layer 10c is set to for example 0.05 GPa or more and 2 GPa or less and/or set to for example 5 times or more and 20 times or less the hardness of the third resin layer 10c. Further, the dielectric tangent of the second resin layer 10b is set to for example 0.01 or more and 0.02 or less, while the thermal expansion coefficients in the thickness direction and plane direction of the second resin layer 10b are set to for example 20 ppm/° C. or more and 50 ppm/° C. or less. Note that, the thickness of the second resin layer 10b is the thickness on the third resin layer 10c.

Further, the second resin layer 10b contains the second filler 12b comprised of many second filler particles formed by an inorganic insulating material. This second filler 12b can be formed by the same material as that for the first filler 12a and can reduce the thermal expansion coefficient of the second resin layer 10b and raise the rigidity of the second resin layer 10b.

The second inorganic insulating layer 11b is formed on the second resin layer 10b and, in the same way as the first inorganic insulating layer 11a included in the base substrate 7 explained above, is configured by an inorganic insulating material which is higher in rigidity, but lower in thermal expansion coefficient and dielectric tangent compared with the resin material, therefore exhibits the same effects as those by the first inorganic insulating layer 11a included in the base substrate 7 explained above.

The thickness of the second inorganic insulating layer 11b is set to for example 3 μm or more and 30 μm or less and/or 0.5 time or more and 10 times or less the thickness of the second resin layer 10b (preferably 0.8 time or more and 1.2 times or less). The rest of the configuration is similar to the above-explained first inorganic insulating layers 11a.

The third resin layer 10c is interposed between the second inorganic insulating layer 11b and the conductive layer 14 and has the same configuration as that of the Above-explained third resin layer 10c included in the base substrate 7. Therefore, it exhibits the same effects as those of the above-explained third resin layer 10c included in the base substrate 7.

The via conductors 15 connect the conductive layers 14 spaced from each other in the thickness direction to each other. They are formed in columnar shapes so that the widths become narrower toward the core board 5. The via conductors 15 can be formed by conductive material such as for example copper, silver, gold, aluminum, nickel, chromium, or the like and are set in thermal expansion coefficient to for example 14 ppm/° C. or more and 18 ppm/° C. or less.

(First and Second Inorganic Insulating Particles)

In this regard, for example, when thermal stress, mechanical stress, or other stress caused due to the difference of the thermal expansion coefficient between the electronic component 2 and the circuit board 3 is applied to the circuit board 3, the first inorganic insulating particles 13a sometimes separate from each other, whereby cracks of the first and second inorganic insulating layers 11a and 11b are generated.

On the other hand, in the circuit board 3, the first and second inorganic insulating layers 11a and 11b include second inorganic insulating particles 13b having larger particle size than the first inorganic insulating particles 13a. Accordingly, even when a crack is generated in the first and second inorganic insulating layers 11a and 11b, when the crack reaches a second inorganic insulating particle 13b, growth of the crack is obstructed since the second inorganic insulating particle 13b has a large particle site. Alternatively, the crack can be diverted along the surface of the second inorganic insulating particle. As a result, the crack is kept from penetrating through the first or second inorganic insulating layer 11a or 11b to reach the conductive layer 14, disconnection of the conductive layer 14 due to the crack as the starting point can be reduced, and consequently a circuit board 3 excellent in the electrical reliability can be obtained. In order to obstruct the growth of a crack or divert a crack, the case where the particle size of the second inorganic insulating particles is 0.5 μm or more is particularly preferred.

Further, the second inorganic insulating particles 13b are large in particle size. Therefore, if the first and second inorganic insulating layers 11a and 11b are configured by only the second inorganic insulating particles, it becomes difficult to arrange many second inorganic insulating particles around one second inorganic insulating particle. Accordingly, the contact area between the second inorganic insulating particles 13b becomes small, and the contact strength between the second inorganic insulating particles 13b is apt to become small. Contrary to this, in the circuit board 3, the first and second inorganic insulating layers 11a and 11b contain not only the second inorganic insulating particles 13b having a large particle size, but also the first inorganic insulating particles 13a having a small particle size, and the second inorganic insulating particles are bonded to each other by a plurality of first inorganic insulating particles 13a arranged around the second inorganic insulating particles. Therefore, the contact area between the second inorganic insulating particles and the first inorganic insulating particles can be made large, and the separation of the second inorganic insulating particles 13b from each other can be reduced. Such an effect becomes particularly conspicuous where the particle size of the first inorganic insulating particles is set to 110 nm or less.

On the other hand, in the circuit board 3, the first inorganic insulating particles 13a are set so that the particle size is a minute 3 nm or more and 110 nm or less. Since the particle size of the first inorganic insulating particles 13a is very small in this way, the first inorganic insulating particles 13a are strongly connected to each other at a temperature less than the crystallization start temperature. As a result, the first and second inorganic insulating particles are connected to each other while the particles themselves keep the amorphous state as they are, so the first and second inorganic insulating layers 11a and 11b become the amorphous state. Therefore, as explained above, the anisotropy of thermal expansion coefficient of the first and second inorganic insulating layers 11a and 11b becomes small. Note that, if the particle size of the first inorganic insulating particles 13a is set so that the particle size is a minute 3 nm or more and 110 nm or less; atoms of the first inorganic insulating particles 13a, particularly atoms on surfaces, actively move. Therefore, even under a low temperature less than the crystallization start temperature, it is guessed that the first inorganic insulating particles 13a are strongly connected to each other. Note that, the “crystallization start temperature” means the temperature at which the crystallization of the amorphous inorganic insulating material starts crystallizing, that is, the temperature at which the volume of the crystal phase region increases.

Further, individual second inorganic insulating particles 13b are covered by the plurality of first inorganic insulating particles 13a so that the second inorganic insulating particles 13b are spaced from each other. As a result, contact of the second inorganic insulating particles 13b which have low bonding strength and are apt to be separated is prevented, separation of the second inorganic insulating particles 13b can be suppressed, and consequently generation of cracks and growth of the same caused by the second inorganic insulating particles can be reduced.

The first inorganic insulating particles 13a and second inorganic insulating particles 13b are preferably made of the same material. As a result, in the first and second inorganic insulating layers 11a and 11b, cracks caused by a difference of material characteristics between the first inorganic insulating particles 13a and the second inorganic insulating particles 13b can be reduced. Further, the first inorganic insulating particles 13a and the second inorganic insulating particles 13b are preferably made of the same materials as those for the first and second fillers 12a and 12b. As a result, the thermal expansion coefficients of the first resin layer 10a and second resin layers 10b can be brought nearer to the thermal expansion coefficients of the first and second inorganic insulating layers 11a and 11b.

The first inorganic insulating particles 13a are preferably spherical in shape. As a result, it becomes easy to fill many first inorganic insulating particles 13a in the voids among the second inorganic insulating particles. In addition, the volume of voids among the first inorganic insulating particles 13a is reduced, the internal structures of the first and second inorganic insulating layers 11a and 11b can be made denser, and the rigidity of the first and second inorganic insulating layers 11a and 11b can be improved.

Further, the second inorganic insulating particles 13b are preferably curved in shape, more preferably are spherical in shape. As a result, the surfaces of the second inorganic insulating particles 13b become smooth, the stress on the surfaces is dispersed, and the generation of cracks of the first and second inorganic insulating layers 11a and 11b from the surfaces of the second inorganic insulating particles 13b as starting points can be reduced.

The second inorganic insulating particles 13b are preferably higher in hardness than the first inorganic insulating particles 13a. In this case, when a crack reaches a second inorganic insulating particle 13b, the growth of the crack to the inside of the second inorganic insulating particle 13b is reduced, and consequently the growth of cracks in the first and second inorganic insulating layers 11a and 11b can be reduced. Further, as will be explained later, the second inorganic insulating particles 13b are easier to increase in hardness than the first inorganic insulating particles. 13a, therefore the rigidity of the first and second inorganic insulating layers 11a and 11b can be easily raised. Note that, the hardness can be measured by using a nano-indenter device.

A width W1 of the first neck structure 17a is preferably larger than a width W2 of the second neck structure 17b. The first inorganic insulating particles 13a and second inorganic insulating particles 13b act like cement and gravel mixed in concrete. That is, the first inorganic insulating particles 13a, in the same way as cement, perform the role of binding the inorganic insulating layers as a whole, while the second inorganic insulating particles 13b, in the same way as gravel, perform the role of strengthening the inorganic insulating layers as a whole. Accordingly, by enlarging the width W1 of the first neck structure 17a, the action of the first inorganic insulating particles 13a for binding the inorganic insulating layers as a whole becomes larger. As a whole, preferable inorganic insulating layers are realized.

(Voids Surrounded by First Inorganic Insulating Particles and Second Inorganic Insulating Particles)

A first inorganic insulating layer 11a, as shown in FIG. 2A and FIG. 3A, has a plurality of voids V surrounded by the first inorganic insulating particles 13a and second inorganic insulating particles 13b in the cross-section cut along the thickness direction or plane direction. In each void V, a portion of the first resin layer 10a is filled (first filling portion 19a). As a result, even if stress is applied to the circuit board 3 and a crack occurs in the first inorganic insulating layer 11a, the growth of the crack can be obstructed or diverted by the first filling portion 19a. Accordingly, the disconnection of the conductive layer 14 caused by the crack can be reduced, and a circuit board 3 excellent in the electrical reliability can be obtained. Note that, each void V is surrounded by a plurality of first inorganic insulating particles 13a and a plurality of second inorganic insulating particles 13b. That is, in each void V, the inner circumferential surface is comprised of a plurality of first inorganic insulating particles 13a and a plurality of second inorganic insulating particles 13b.

Further, each first filling portion 19a contains more of a resin material having a lower Young's modulus compared with the inorganic insulating material than the first inorganic insulating layer 11a. Therefore, when stress is applied to the circuit board 3, the first filling portions 19a arranged in the voids in the first inorganic insulating layer 11a enable the stress applied to the first inorganic insulating layer 11a to be eased and enable the generation of cracks in the first inorganic insulating layer 11a caused by the stress to be reduced. In each void V, the height in the thickness direction of the first inorganic insulating layer 11a in the cross-section is preferably set to 0.3 μm or more and 5 μm or less, while the width in the plane direction of the first inorganic insulating layer 11a in the cross-section is preferably set to 0.3 μm or more and 5 μm or less.

Each void V is surrounded by the first inorganic insulating particles 13a and second inorganic insulating particles 13b in the cross-section cut along the thickness direction. However, in the three-dimensional shape, a portion extends along the direction perpendicular with respect to the cross-section (Y-direction), while another portion extends along the thickness direction of the first inorganic insulating layer 11a (Z-direction), whereby the void is connected to an opening O which is formed in one major surface of the first inorganic insulating layer 11a, which contacts the first resin layer 10a, and becomes an open pore. Therefore, a portion of the first resin layer 10a is filled in the void V through the opening O. In this opening O, the width along the plane direction is preferably set to 1 μm or more and 20 μm or less.

Note that, the opening O was filled with a portion of the first resin layer 10a, but in place of the first resin layer 10a, a portion of the third resin layer 10c may be filled as well or a portion of the two layers of the first resin layer 10a and third resin layer 10c may be filled as well. In the latter case, filling a larger amount of the first resin layer 10a in the opening O than the third resin layer 10c is preferred.

Further, the first filling portion 19a does not have to completely fill the void V. It is sufficient that a portion of the first resin layer be arranged in the void V.

Each first inorganic insulating layer 11a desirably has a three-dimensional mesh-like structure by mutual bonding of the first inorganic insulating particles 13a and second inorganic insulating particles 13b. As a result, the effect the first filling portion 19a in reduction of cracks in the first inorganic insulating layer 11a can be raised.

Further, in each first inorganic insulating layer 11a, interposition of the first inorganic insulating particles 13a between the second inorganic insulating particles 13b and each first filling portion 19a is desirable. As a result, compared with a case where the surfaces of the second inorganic insulating particles 13b and the first filling portions 19a directly abut, the first inorganic insulating particles 13a enable wettability of the surface of the first inorganic insulating layer 11a by the first filling portions 19a to be raised, so in the voids V, the first filling portions 19a can be efficiently filled.

Further, each first inorganic insulating layer 11a preferably has projection portions 18b which are projected from the inner walls of the voids V toward the first filling portions 19a and include at least portions of single second inorganic insulating particles 13b. In this case, large surface relief is formed on the surface of the inner wall of each void V. Due to an anchor effect, the bonding strength between the first inorganic insulating layer 11a and the first filling portions 19a is raised, and separation between the first inorganic insulating layer 11a and the first filling portions 19a can be reduced. The projection portions 18b are set in length in the projection direction to for example 0.1 μm or more and 2 μm or less and set in width to for example 0.1 μm or more and 2 μm or less. Note that, the projection portions 18b may include a plurality of second inorganic insulating particles 13b as well.

Further, each first filling portion 19a preferably has a fourth filler comprised of fourth filler particles which are formed by an inorganic insulating material. The fourth filler is preferably smaller in content than the first filler 12a included in the first resin layer 10a. As a result, in the first filling portion 19a, the content ref the resin material is raised, and the crack reduction effect on the first inorganic insulating layer 11a by the first filling portion 19a can be raised. The content of the fourth filler in this first filling portion 19a is set to for example 0 vol % or more and 10 vol % or less and is set to for example 0% or more and 30% or less, of the content of the first filler 12a in the first resin layer 10a.

Note that, the second inorganic insulating layer 11b arranged on the second resin layer 10b, as shown in FIG. 2B, has the same construction as that of the first inorganic insulating layers 11a. Further, in the second inorganic insulating layer 11b, portions of the second resin layer 10b are filled in the voids V (second filling portions 19b).

(Gaps Among First Inorganic Insulating Particles)

As explained above, in the first inorganic insulating layers 11a, a plurality of first inorganic insulating particles 13a are connected to each other at the first neck structures 17a. Note, in the first inorganic insulating layers 11a, integral bonding of particles as in a sintered inorganic insulating layer is not achieved. The first neck structures 17a are maintained, while the plurality of inorganic insulating particles 13a form a frame structure in which first gaps G1 are formed. In the first gaps G1, the resin of the first resin layer 10a is filled (third filling portions 19c).

Accordingly, in the first inorganic insulating layers 11a, due to the frame structure of the inorganic insulating material, a low thermal expansion coefficient is realized. By reinforcement of the frame structure by the third filling portions 19c made of a resin, a high strength is realized.

Further, second gaps G2 are formed between single second inorganic insulating particles 13b and a plurality of first inorganic insulating particles 13a around them. In the second gaps G2 as well, the resin of the first resin layer 10a is filled (fourth filling portions 19d). The fourth filling portions 19d, in the same way as the third filling portions 19c, also contribute to the reinforcement of the frame structure by the first inorganic insulating particles 13a and second inorganic insulating particles 13b.

The first gaps G1 and second gaps G2 are formed due to the fact that the first inorganic insulating particles 13a are not made denser and have sizes schematically (in terms of order) of the extent of the size, of the first inorganic insulating particles 13a. Accordingly, since the particle size of the first inorganic insulating particles 13a is preferably 3 nm or more and 110 nm or less, in the first gaps G1 and second gaps G2, the sizes on a predetermined cross-section of the first inorganic insulating layers 11a are preferably 3 nm or more and 110 nm or less. Further, on the predetermined cross-section of the first inorganic insulating layers 11a, the area of the first gaps G1 or second gaps G2 is for example not more than 2 times the area of the first inorganic insulating particles 13a. By setting the first gaps G1 and second gaps G2 to such a size and/or area, it is possible to maintain the denseness of the first inorganic insulating layers 11a while filling the resin in the first, gaps G1 and second gaps G2.

Note that, as will be explained later, the voids V are influenced by the volume % of the second inorganic insulating particles 13b. The voids V schematically (in terms of order) become a size to an extent of the distance between the second inorganic insulating particles 13b or more. Accordingly, the sizes of the first gaps G1 and second gaps G2 are larger than the sizes of the voids. V by a difference of an extent of the difference between the size of the second inorganic insulating particles 13b and the size of the first inorganic insulating particles 13a. For example, assuming that the particle size of the first inorganic insulating particles 13a is 3 nm or more and 110 nm or less and the particle size of the second inorganic insulating particles 13b is 0.5 μm or more and 5 μm or less, the sizes of the first gaps G1 and second gaps G2 are 0.0006 to 0.22 time (3 nm/5 μm to 110 nm/0.5 μm) the size of the voids V. More preferably, they are 0.005 to 0.1 time the sizes of the voids V. Note that, on a predetermined cross-section of the first inorganic insulating layers 11a, the area of the voids V is for example 0.5 time or more the area of the second inorganic insulating particles 13b.

Further, on a predetermined cross-section of the first inorganic insulating layers 11a, there are portions where the voids V and the second gaps G2 contact the second inorganic insulating particles 13b, but in contrast the first gaps G1 are surrounded by the first inorganic insulating particles 13a and contact only the first inorganic insulating particles 13a. This characteristic feature is useful for differentiating the first gaps G1 and the voids V.

The first gaps G1 are, in the same way as the voids V, surrounded by the first inorganic insulating particles 13a on a predetermined cross-section. However, in the three-dimensional shape, a portion extends along the direction perpendicular with respect to the cross-section (Y-direction), while another portion extends along the thickness direction of the first inorganic insulating layers 11a (Z-direction), whereby a gap is connected to a not shown opening which is formed in one major surface of the first inorganic insulating layer 11a which contacts the first resin layer 10a and becomes an open pore. Therefore, a portion of the first resift layer 10a is filled in the first gap G1 through the opening. Note that, also the second gap G is connected, directly or through the first gap G1, to a not shown opening formed in one major surface of the first inorganic insulating layer 11a which contacts the first resin layer 10a.

Further, the first gaps G1 and the second gaps G2 are, in the same way as being connected to openings formed in the major surfaces of the first inorganic insulating layers 11a, communicated with the voids V (first filling portions 19a and second filling portions 19b). Accordingly, the first gaps G1 and second gaps G2 are supplied with the resin of the first resin layer 10a through the voids V. That is, since a plurality of voids V are spread about, filling of resin into the first gaps G1 and second gaps G2 is promoted. Further, the first filling portions 19a and second filling portions 19b are fixed at their peripheral portions to the third filling portions 19c and fourth filling portions 19d, therefore separation from the inorganic insulating layers is suppressed.

Note that the first gaps G1 and second gaps G2 are filled with portions of the first resift layer 10a, however, place of the first resin layer 10a, portions of the third resin layers 10c may be filled as well or portions of the two layers of the first resin layer 10a and third resin layers 10c may be filled as well. In the latter case, a larger amount of the first resin layer 10a than the third resin layers 10c is preferably filled in the first gaps G1 and second gaps G2.

Further, the third filling portions 19c do not have to completely fill the first gaps G1. It is sufficient that a portion of the first resin layer be arranged in the first gaps G1. This same is true also for the fourth filling portions 19d.

The first gaps G1 and second gaps G2 are relatively small, therefore the third filling portions 19c and fourth filling portions 19d contain no or almost no first filler particles which are contained in the first resin layer 10a. For example, if the particle size of the first filler particles is 0.5 μm or more and 5.0 μm or less, the third filling portions 19d and fourth filling portions 19d do not contain first filler particles. This characteristic feature is also useful for differentiating the first gaps G1 and second gaps G2 from the voids V.

As explained above, the first inorganic insulating particles 13 are preferably spherical in shape. In this case, the frame structure configured by the first inorganic insulating particles 13a and the filling portions permeating through the frame structure are easily homogenously formed and portions at which stress concentration etc. easily occur are hardly ever formed. Therefore, as a whole, the strength is improved.

Note that, although not particularly shown, for the second inorganic insulating layer 11b as well, the first gaps G1 and second gaps G2 are formed in the same way as the first inorganic insulating layers 11a. In the first gaps al and second gaps G2, the resin of the second resin layers 10b (and/or third resin layers 10c) is filled (third filling portions 19c and fourth filling portions 19d).

<Steps of Production of Circuit Board>

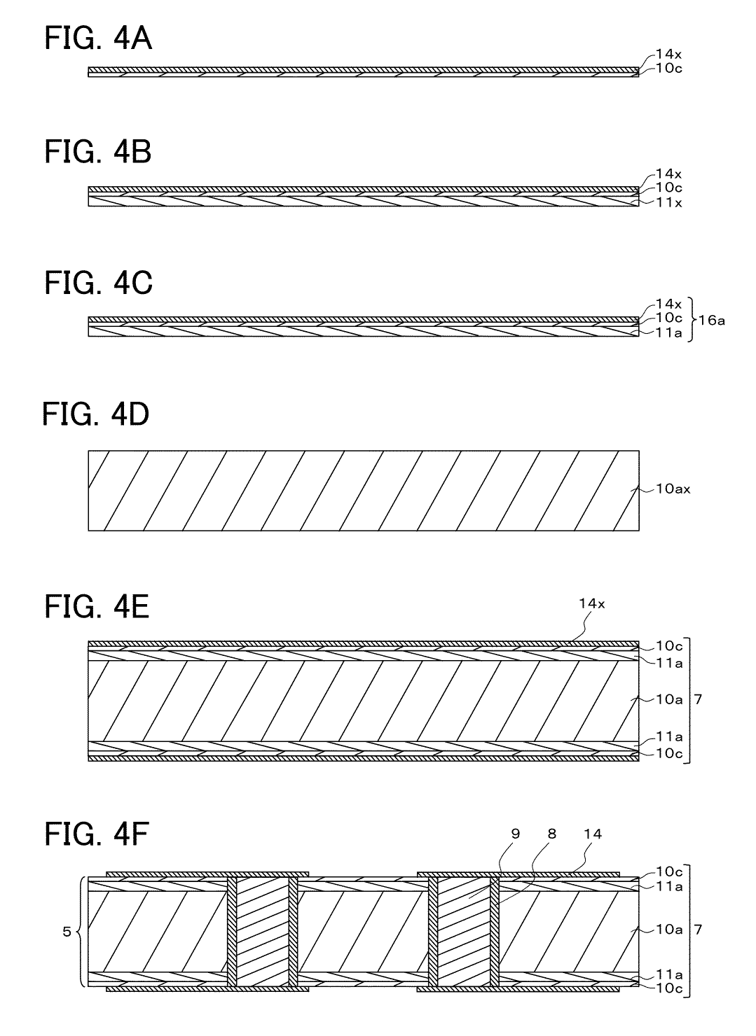

Next, a method of production of the above-explained circuit board 3 will be explained based on FIG. 4 to FIG. 6.

The method of production of the circuit board 3 is comprised of a step of preparation of the core board 5 and a step of build-up of circuit layers 6.

(Step of Preparation of Core Board 5)

(1) An inorganic insulating sol fix having a solid containing first inorganic insulating particles 13a and second inorganic insulating particles 13b and a solvent are prepared.

The inorganic insulating sol 11x contains, for example, the solid to 10 vol % or more and 50 vol % or less and contains the solvent to 50 vol % or more and 90 vol % or less. Due to this, it is possible to hold the viscosity of the inorganic insulating sol 11x low while maintaining a high productivity of the inorganic insulating layer formed by the inorganic insulating sol 11x.

The solid of the inorganic insulating sol 11x, for example, contains the first inorganic insulating particles 13a to 20 vol % or more and 40 vol % or less and contains the second inorganic insulating particles 13b to 60 vol % or more and 80 vol % or less. Due to this, in the step of (3) explained later, the generation of cracks in the first inorganic insulating layers 11a can be effectively reduced.

Note that, the first inorganic insulating particles 13a, when they are made of silicon oxide, for example, can be manufactured by refining silicate compound such as aqueous solution of sodium silicate (water glass) or the like and chemically precipitating silicon oxide. In this case, the first inorganic insulating particles 13a can be manufactured under low temperature conditions, therefore the first inorganic insulating particles 13a can be manufactured in the amorphous state. Further, the particle size of the first inorganic insulating particles 13a is adjusted by adjusting the precipitation time of the silicon oxide. Specifically, the longer the precipitation time, the larger the particle size of the first inorganic insulating particles 13a.

On the other hand, the second inorganic insulating particles 13b, when they are made of silicon oxide, for example, can be manufactured by refining silicate compound such as aqueous solution of sodium silicate (water glass) or the like, and chemically precipitating silicon oxide, spraying the thus obtained solution into a flame, and reducing the formation of aggregates while heating to 800° C. or more and 1500° C. or less. Therefore, the second inorganic insulating particles 13b have a larger particle size compared with the first inorganic insulating particles 13a, therefore the formation of aggregates at the time of high temperature heating is easily reduced, the particles can be easily manufactured by high temperature heating, and consequently the hardness can be easily raised.

Further, the heating time when preparing the second inorganic insulating particles 13b is preferably set to 1 second or more and 180 seconds or less. As a result, by shortening the heating time, even in a case where the heating is carried out to 800° C. or more and 1500° C. or less, the crystallization of the second inorganic insulating particles 13b is suppressed, and the amorphous state can be maintained.

On the other hand, as the solvent contained in the inorganic insulating sol 11x, for example, methanol, isopropanol, n-butanol, ethylene glycol, ethylene glycol monopropyl ether, methyl ethyl ketone, methyl isobutyl ketone, xylene, propylene glycol monomethyl ether, propylene glycol monomethyl ether acetate, dimethyl acetoamide, and/or an organic solvent containing a mixture of two or more types, selected from among them can be used. Among them, an organic solvent containing methanol, isopropanol, or propylene glycol monomethyl ether is desirable. As a result, the inorganic insulating sol 11x can be uniformly coated, and, in addition, in the step of (3) which will be explained later, the solvent can be efficiently evaporated.

(2) Next, as shown in FIG. 4A and FIG. 4B, a resin-coated metal foil having the third resin layer 10c and a metal foil 14x made of copper or another conductive material is prepared, and the inorganic insulating sol 11x is coated on one major surface of the third resin layer 10c, to thereby form the inorganic insulating sol 11x in a layer state.

The resin-coated metal foil can be formed by coating the metal foil 14x with a resin varnish by using a bar coater, die coater, curtain coater, or the like and drying. The third resin layer 10c formed in the present step is for example a B stage or a C stage.

The inorganic insulating sol 11x can be coated by using, for example, a dispenser, bar coater, die coater, or screen printing. At this time, as explained above, the solid of the inorganic insulating sol 11x is set to 50 vol % or less, therefore the viscosity of the inorganic insulating sol 11x is set low, and the flatness of the coated inorganic insulating sol 11x can be raised.

Further, the particle size of the first inorganic insulating particles 11a is, as explained above, set to 3 nm or more. Therefore, also by this, the viscosity of the inorganic insulating sol 11x is reduced well, and the flatness of the coated inorganic, insulating sol 11x can be improved.

(3) Next, the inorganic insulating sol 11x is dried and the solvent is evaporated.

The inorganic insulating sol 11x is dried by for example heating and air drying. The drying temperature is, for example, set to be 20° C. or more and less than the boiling point of the solvent (where two or more types of solvents are mixed, the boiling point of the solvent having the lowest boiling point), while the drying time is set to for example 20 seconds or more and 30 minutes or less. As a result, the boiling action of the solvent is reduced, pushout of the first and second inorganic insulating particles 13a and 13b due to the pressure of bubbles generated at time of the boiling action is suppressed, and it becomes possible to make the distribution of the particles more uniform.

During drying, the contact portions of the first and second inorganic insulating particles 13a and 13b (the first neck structures 17a and second neck structures 17b) become thicker. However, the sol is not heated to a high temperature, therefore the neck structures can be maintained, and a frame structure is formed by the first inorganic insulating particles 13a (the first gaps G1 and second gaps G2 are formed). Further, the first inorganic insulating particles 13a are, compared with the second inorganic insulating particles 13b, active in the motion of atoms, therefore the first neck structures 17a formed by the first inorganic insulating particles 13a becomes thicker than the second neck structures 11b formed by the first inorganic insulating particles 13a and second inorganic insulating particles 13b.

Along with the evaporation of the solvent, the inorganic insulating sol 11x shrinks, but the solvent is contained in the gaps among the first and second inorganic insulating particles 13a and 13b and is not contained in the first and second inorganic insulating particles 13a and 13b themselves. For this reason, if the inorganic insulating sol 11x contains second inorganic insulating particles 13b having a large particle size, the region in which the solvent is filled becomes smaller by that amount. Therefore, at the time of evaporation of the solvent of the inorganic insulating sol 11x, the shrinkage of the inorganic insulating sol 11x becomes small. That is, due to the second inorganic insulating particles 13b, the shrinkage of the inorganic insulating sol 11x is restricted. As a result, the generation of cracks caused by the shrinkage of the inorganic insulating sol 11x can be reduced. Further, even if a crack occurs, the growth of the crack can be prevented by the second inorganic insulating particles 13b having the large particle size.

When the second inorganic insulating particles 13b having particle size of 0.5 μm or more are contained in the solid content of the inorganic insulating sol 11x to 60 vol % or more, the second inorganic insulating particles 13b approach each other, and many regions surrounded by these second inorganic insulating particles 13b are formed. In this state, if the solvent filled in gaps among the second inorganic insulating particles 13b is evaporated, in the gaps, shrinkage of the first inorganic insulating particles 13a occurs, and voids V are formed. As a result, voids V surrounded by the first inorganic insulating particles 13a and second inorganic insulating particles 13b can be formed.

Further, when the second inorganic insulating particles 13b having a particle size of 0.5 μm or more are contained to 60 vol % or more, the second inorganic insulating particles 13b easily approach each other. On the other hand, the solvent easily remain in facing regions of the second inorganic insulating particles 13b, and the residual solvent contains many first inorganic insulating particles 13a. Then, when the residual solvent is evaporated, along with the evaporation of the solvent, the first inorganic insulating particles 13a contained in the solvent coagulate at the facing regions of the second inorganic insulating particles. As a result, the first inorganic insulating particle 13a can be interposed between the second inorganic insulating particles 13b. In order to interpose the first inorganic insulating particles 13a well between the second inorganic insulating particles 13b, the solid of the inorganic insulating sol 11x desirably contains the first inorganic insulating particles 13a to 20 vol % or more.

Further, compared with the regions including the second inorganic insulating particles 13b, in the regions including the first inorganic insulating particles 13a, the solvent is evaporated in a large amount and large shrinkage occurs, therefore projection portions 18b are formed.

Note that, the particle size or content of the first inorganic insulating particles 13a or second inorganic insulating particles 13b, the type or amount of the solvent of the inorganic insulating sol 11x, the drying time, drying temperature, amount of air or air flow at the time of drying, or heating temperature or heating time after drying can be suitably adjusted so that the voids V are formed to desired shapes.

(4) The remaining solid of the inorganic insulating sol 11x is heated. From the inorganic insulating sol 11x, the first inorganic insulating layer 11a is therefore formed. As a result, a first laminate sheet 16a, as shown in FIG. 4C, which has a metal foil 14x, third resin layer 10c, and first inorganic insulating layer 11a is obtained.

Here, the inorganic insulating sol 11x of the present embodiment has first inorganic insulating particles 13a set in particle size to 110 nm or less. As a result, even when the heating temperature of the inorganic insulating sol 11x is a relatively low temperature, for example, a low temperature of less than the crystallization start temperature of the first inorganic insulating particles 13a and second inorganic insulating particles 13b, the first inorganic insulating particles 13a can be strongly bonded with each other. Note that, when first inorganic insulating particles 13a formed by silicon oxide are used, the temperature at which the inorganic insulating particles 13a can be strongly bonded with each other is about 250° C., for example, when the particle size of the inorganic insulating particles 13a is set to 110 nm or less and is about 150° C. when the particle size is set to 15 nm or less. Further, when the first and second inorganic insulating particles 13a and 13b are made of silicon oxide, their crystallization start temperature is about 1300° C.

Further, in the present embodiment, the heating temperature of the inorganic insulating sol 11x is set to less than the thermal decomposition start temperature of the third resin layers 10c. As a result, the deterioration of characteristics of the third resin layers 10c can be suppressed. Note that, when the third resin layers 10c are made of an epoxy resin, the thermal decomposition start temperature is about 280° C. Further, the thermal decomposition start temperature is, in thermogravimetry according to ISO11358:1997, a temperature where the mass of the resin is reduced by 5%.

The heating temperature of the inorganic insulating sol 11x is, in order to evaporate the solvent which remains, set at the boiling point of the solvent or more. Further, the above heating temperature is preferably set to less than the crystallization start temperature of the first inorganic insulating particles 13a and second inorganic insulating particles 13b. In this case, the crystallization of the first inorganic insulating particles 13a and second inorganic insulating particles 13b is reduced, and the ratio of the amorphous state can be raised. As a result, the shrinkage of the crystallized first inorganic insulating layers 11a due to the phase transition is reduced, and the generation of cracks in the first inorganic insulating layers 11a can be reduced.

Note that, the heating of the inorganic insulating sol 11x is set in temperature to for example 100° C. or more and less than 220° C., is set in time to for example 0.5 hour or more and 24 hours or less, and is carried out in for example the ambient atmosphere. Note that, when the heating temperature is set at 150° C. or more, in order to suppress the oxidation of the metal foil 14x, the heating of the inorganic insulating sol 11x is desirably carried out in vacuum or in argon or another inert gas atmosphere or in a nitrogen atmosphere.

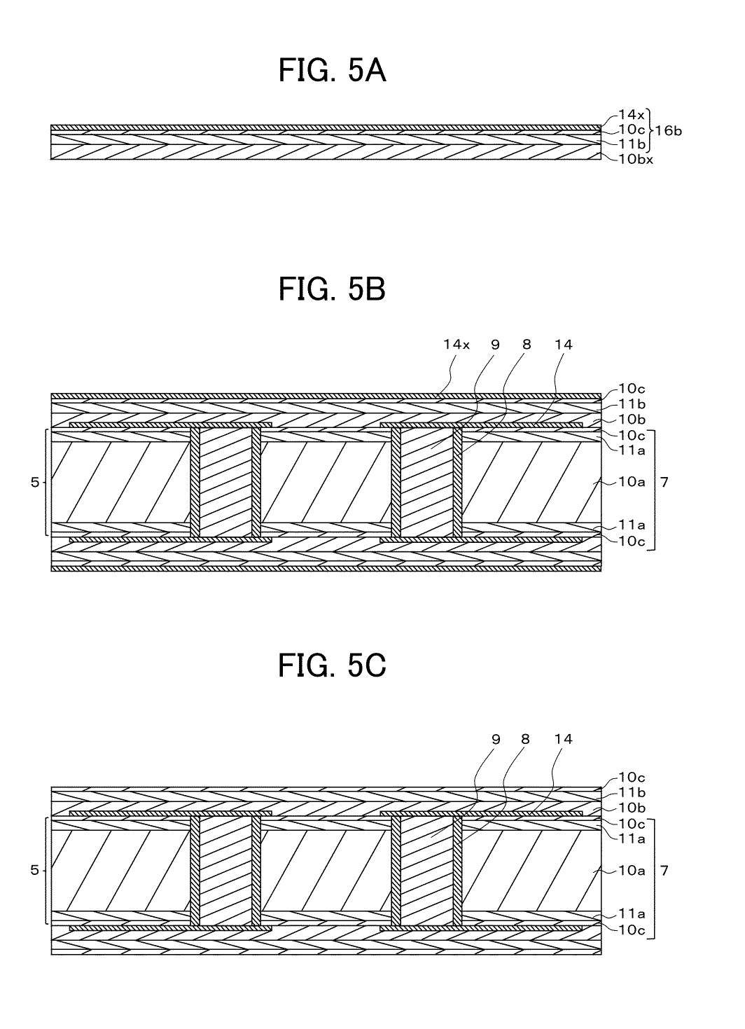

(5) A first resin precursor sheet 10ax as shown in FIG. 5D is prepared, then first laminate sheets 16a are laid on the top and bottom surfaces of the first resin precursor sheet 10ax.

The first resin precursor sheet 10ax, for example, can be manufactured by laminating a plurality of resin sheets including uncured heat curing resin and base materials. Note that, “uncured” is the state of the A stage or B stage according to ISO472:1999.

The first laminate sheets 16a are laid so that the first inorganic insulating layers 11a are interposed between the metal foils 14x and the first resin precursor sheet 10ax.

(6) Next, the laminate assembly is hot pressed in the up-down direction so as to, as shown in FIG. 4E, cause the first resin precursor sheet 10ax to cure to form the first resin layer 10a.

The heating temperature of the laminate assembly is set at the curing start temperature of the first resin precursor sheet 10ax or more and less than the thermal decomposition temperature. Specifically, when the first resin precursor sheet is made of an epoxy resin, cyanate resin, bismaleimide triazine resin, or polyphenylene ether resin, the heating temperature is set at for example 170° C. or more and 230° C. or less. Further, the pressure of the laminate assembly is set to for example 2 MPa or more and 3 MPa or less, and the heating time and pressing time are set to for example 0.5 hour or more and 2 hours or less. Note that, the curing start temperature is a temperature where the resin becomes the state of the C stage according to ISO472:1999.

By the heating for curing, the first resin precursor sheet 10ax is temporarily liquefied and permeates through the first inorganic insulating layers 11a. Due to this, the resin is filled in the voids V to form the first filling portions 19a. Further, the resin is filled in the first gaps G1 and second gaps G2 to form the third filling portions 19c and fourth filling portions 19d.

Note that, the permeation is thought to occur by capillary action. The capillary action becomes larger inversely proportional to the gap size. Accordingly, since the particle size of the first inorganic insulating particles 13a is small, the sizes of the first gaps G1 and second gaps G2 are small, but the capillary action becomes large, therefore the resin is sufficiently permeates through the first inorganic insulating layers 11a.

(7) As shown in FIG. 4F, through-hole conductors 8 penetrating through the base substrate 7 in the thickness direction and insulators 9 inside the through-hole conductors 8 are formed, then conductive layers 14 connected to the through-hole conductors 8 are formed on the base substrate 7.

The through-hole conductors 8 and insulators 9 are formed as follows. First, for example, drilling or lasering etc. is used to form a plurality of through-holes penetrating through the base substrate 7 and metal foils 14x in the thickness direction. Next, for example, electroless plating, vapor deposition, CVD, or sputtering is used to coat a conductive material on the inner walls of the through-holes to thereby form cylindrical through-hole conductors 8. Next, the internal portions of the cylindrical through-hole conductors 8 are filled with a resin material etc. whereby the insulators 9 are formed.

Further, the conductive layers 14 are formed as follows. First, the insulators 9 and through-hole conductors 8 exposed from the insides of the through-holes formed in the metal foils 14x are, for example, coated by electroless plating, vapor deposition, CVD, or sputtering with metal layers made of the same metal material as that for the metal foils 14x. Next, photolithography, etching, or the like is used to pattern the metal foils 14x and/or metal layers to thereby form the conductive layers 14. Note that, it is also possible to peel off the metal foils 14x once, form metal layers on the base substrate 7, then pattern the metal layers so as to form the conductive layers 14.

The core board 5 can be manufactured as explained above.

(Build-up Step of Circuit Layers 6)

(8) A second resin precursor sheet 10bx and second laminate sheet 16b are newly prepared, then, as shown in FIG. 5A, the second laminate sheet 16b is laid on the second resin precursor sheet 10bx.

The second resin precursor sheet 10bx is formed by the above-explained uncured heat curing resin which configures the second resin layer 10b.

Further, the second laminate sheet 16b is for example manufactured by the same steps as the steps of (1) to (4), includes the metal foil 14x, third resin layer 10c, and second inorganic insulating layer 11b, and is placed on the second resin precursor sheet 10bx so that the second inorganic insulating layer 11b abuts against the second resin precursor sheet 10bx.

(9) Next, such a second laminate sheet 16b is laid on each of the top and bottom surfaces of the core board 5 with the second resin precursor sheet 10bx interposed therebetween.

(10) The laminate assembly of the core board 5 and second laminate sheets 16b is hot pressed in the up/down direction to thereby, as shown in FIG. 5B, cause the heat curing resins of the second resin precursor sheets 10bz to be cured and make the second resin precursor sheets 10bx the second resin layers 10b. The hot pressing of the laminate assembly for example can be carried out in the same way as the step of (6).

In this step, in the same way as the step of (6) in which the resin of the first resin layer 10a permeates through the voids V and first gaps G1 and second gaps G2 of the first inorganic insulating layers 11a, the resin of the second resin layers 10b permeates through the voids V and first gaps G1 and second gaps G2 of the second inorganic insulating layers 11b. Due to this, the second filling portions 19b and third filling portions 19c of the second inorganic insulating layers 11b are formed.

(11) As shown in FIG. 5C, for example, an etching method using a mixed solution of sulfuric acid and a hydrogen peroxide solution, a ferric chloride solution, or a cupric chloride solution is used to peel off the metal foils 14x from, the second inorganic insulating layers 11b.

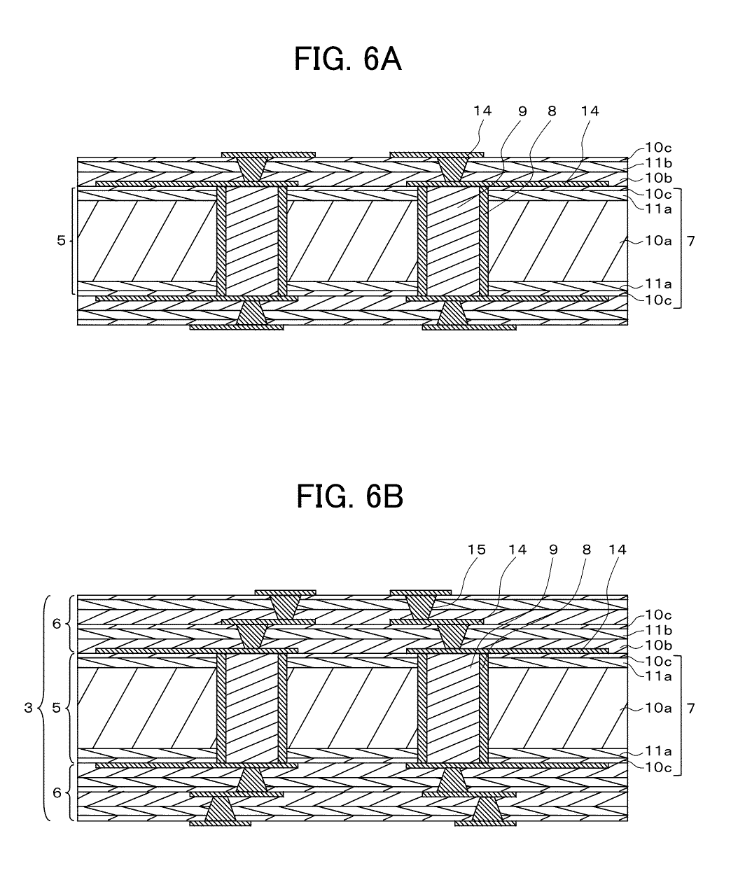

(12) As shown in FIG. 6A, via conductors 15 which penetrate through the second resin layers 10b, second inorganic insulating layers 11b, and third resin layers 10c in the thickness direction are formed, and the conductive layers 14 are formed on the second inorganic insulating layers 11b.

The via conductors 15 and conductive layers 14, are specifically formed as follows. First, for example, a YAG laser apparatus or carbon dioxide gas laser apparatus is used to form via holes penetrating through the second resin layers 10b, second inorganic insulating layers 11b, and third resin layers 10c. Next, for example, by a semi-additive process, subtractive process, or full-additive process, the via holes are formed with the via conductors 15 and the third resin layers 10c are coated with the conductive material to form the conductive layers 14. Note that, the conductive layers 14 may, be formed so that, at step (11), the metal foils 14x are not peeled off, but the metal foils 14x are patterned as well.

(13). As shown in FIG. 68, the steps of (8) to (12) are repeated to form circuit layers 6 on the top and bottom of the core board 5. Note that, by repeating the present steps, it is possible to increase the number of the circuit layers 6.

The circuit board 3 can be manufactured in the above-described way. Note that the obtained circuit board 3 may have the electronic component 2 flip mounted to it by the bumps 4 interposed therebetween to manufacture the mounting structure 1 shown in FIG. 1.

Note that, the electronic component 2 may be electrically connected to the circuit board 3 by wire bonding or may be built-in the circuit board 3 as well.

The present invention is not limited to the above-explained embodiment. Various alterations, improvements, combinations, etc. are possible in the range not out of the gist of the present invention.

In the above-explained embodiment, the example of applying the present invention to a circuit board was explained. However, the invention is not limited to a circuit board. It can be applied to all structures having the above-explained inorganic insulating layers. For example, the present invention can also be applied to the case of an electronic device such as a mobile phone or the like. In this case, the inorganic insulating layers are used as abrasion resistant films which protect the case. Further, the present invention can also be used for windows used for automobiles, houses, etc. In this case, the inorganic insulating layers can be used as transparent abrasion resistant sheet coating films which cover the window surface. As a result, reduction of transparency due to scratches of the window material surface can be suppressed. Further, the present invention can be applied to a die used for die casting. In this case, the inorganic insulating layers can be used as abrasion resistant coating films or insulati films coating the die surface.

Further, in the above-explained embodiment of the present invention, as the example of the circuit board according to the present invention, a built-up multilayer board comprised of a core board and circuit layers was mentioned. However, at examples of the circuit board according to the present invention, other than a built-up multilayer board, for example, an interposer board, a coreless board, or a single layer board configured by only a core board, a ceramic board, a metal board, and a core board including a metal plate are included as well.

Further, in the above-explained embodiment of the present invention, the inorganic insulating layers included the first inorganic insulating particles and second inorganic insulating particles. However, the inorganic insulating layers need only contain the first inorganic insulating particles. The second inorganic insulating particles need not be contained in the inorganic insulating layers. Further, inorganic insulating particles which are different in particle size from the first inorganic insulating particles and second inorganic insulating particles may be contained in the inorganic insulating layers as well.

Further, in the above-explained embodiment of the present invention, the first resin layer and second resin layers were formed by heat curing resins. However, one or both of the first resin layer and second resin layers may be formed by a thermoplastic resin as well. As this thermoplastic resin, for example, a fluorine resin, aromatic liquid crystal polyester resin, polyether ketone resin, polyphenylene ether resin, polyimide resin, etc. can be used.

Further, in the above-explained embodiment of the present invention, the circuit board was provided with third resin layers, but the third resin layers need not be provided. In this case, the conductive layers are formed on the first inorganic insulating layers and second inorganic insulating layers. Further, at step (2), the inorganic insulating sol is coated on the metal foils.

Further, in the above-explained embodiment of the present invention, the third resin layers were set lower in Young's modulus compared with the second resin layers. However, the third resin layers and the second resin layers may be the same in young's modulus as well. In this case, for example, third resin layers and second resin layers formed by the same resin material can be used.

Further, in the above-explained embodiment of the present invention, the two of the core board and circuit layer were provided with inorganic insulating layers. However, in the circuit board, at least either one of the core board or circuit layer may be provided with the inorganic insulating layer.

Further, in the above-explained embodiment of the present invention, the inorganic insulating layers had voids surrounded by the first inorganic insulating particles and second inorganic insulating particles and had resin filled in these voids (first and second filling portions). However, these voids and filling portions also need not be provided. In this case, the upper limit value of vol % of the first inorganic insulating particles contained in the inorganic insulating layers may be smaller than that in the embodiment and the lower limit value of vol % of the second inorganic insulating particles contained in the inorganic insulating layers may be larger than that in the embodiment. For example, the inorganic insulating layers may contain the first inorganic insulating particles to 20 vol % or more and 90 vol % or less and contain the second inorganic insulating particles to 10 vol % or more and 90 vol % or less.

Further, in the above-explained embodiment of the present invention, the evaporation of the solvent at step (3) and the heating of the solvent at step (4) were separately carried out. However, the step (3) and the step (4) may be simultaneously carried out as well.

Further, in the Above-explained embodiment of the present invention, at the step of (8), uncured second resin precursor sheets were placed, on the second inorganic insulating layers. However, an uncured liquid-state second resin layer precursor may also be coated on the second inorganic insulating layers.

### Examples

Below, the present invention will be explained in detail according to an example, but the present invention is not limited by the following example. Alterations and modes of working within a range not out of the gist of the present invention are all included in the scope of the present invention.

A multilayer board provided with a metal foil, a first inorganic insulating layer comprised of inorganic insulating particles, and a first resin layer was manufactured. Then, the first inorganic insulating layer of the multilayer board was cut to a thin slice and the thus obtained sample was photographed by using a transmission electron microscope (TEM) to observe the structure of the first inorganic insulating layer.

(Conditions for Preparation of Multilayer Board)

First, a first inorganic, insulating sol containing first inorganic insulating particles and a second inorganic insulating sol containing second inorganic insulating particles were prepared. Next, the first inorganic insulating sol and second inorganic insulating sol were blended in predetermined amounts and were uniformly mixed.

By this method, an inorganic insulating sol was prepared. The inorganic insulating sol, as the solid, contains the first inorganic insulating particles (mean particle size:40 nm, solid ratio:30%) and second inorganic insulating particles (mean particle size:1 μm, solid ratio:70%), and contains the solvent to 42 mass %.

Next, the inorganic insulating sol was coated on the third resin layer of the resin-coated metal foil. The third resin layer was formed by an epoxy resin.

Next, under conditions of a temperature of 150° C., a time of 2 hours, and an atmosphere of the ambient air, the inorganic insulating sol was heated to evaporate the solvent and manufacture a laminate sheet.

Next, a laminate sheet was laid on each of the top and bottom surfaces of a first resin precursor sheet containing the uncured heat curing resin. Under conditions of a time of 1 hour, a pressure of 3 MPa, and a temperature of 180° C., the laminate assembly was hot pressed to thereby to make the first resin precursor sheet the first resin layer and manufacture the multilayer board.

### Example

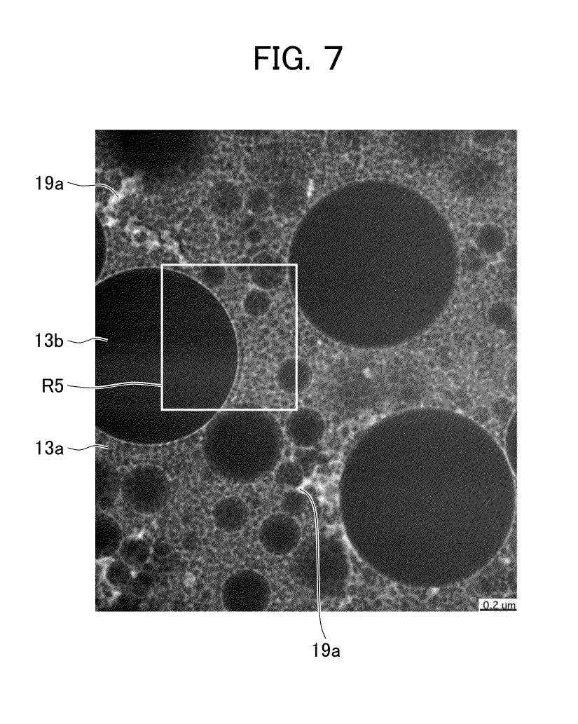

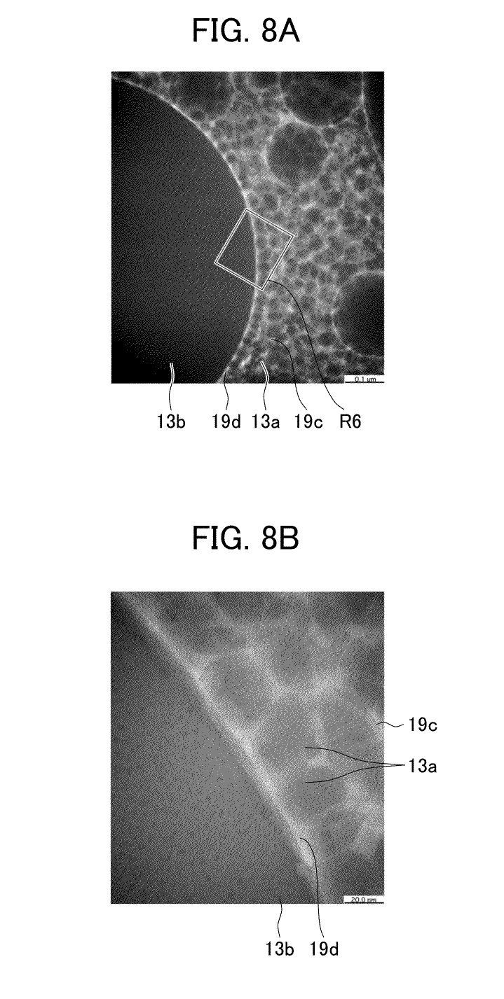

In the photographs of FIG. 7, FIG. 8A, and FIG. 88, materials through which electrons easily pass are expressed white, while materials through which they are hard to pass are expressed black. That is, portions expressed black show the inorganic insulating material, and portions expressed white show the resin.

In FIG. 7, among the second inorganic insulating particles 13b, formation of white regions and formation of the first filling portions 19a are observed. Further, in FIG. 7, FIG. 8A, and FIG. 8B, the peripheries of the first inorganic insulating particles 13a became white. It was confirmed that the third filling portions 19c and fourth filling portions 19d were formed.

Note that, the first neck structures 17a and second neck structures 17b are hard to clearly observed as in FIG. 3B. This is because, the inorganic insulating particles are formed in spherical shapes. The inorganic insulating particles basically contact each other by point-contact. Therefore, the probability that the captured cross-section coincides with the contact points (neck structures) is low.

### REFERENCE SIGNS LIST

1 mounting structure
2 electronic component
3 circuit board
4 bump
5 core board
6 circuit layer
7 base substrate
8 through-hole conductor
9 insulator
10a first resin layer
10ax first resin precursor sheet
10b second resin layer
10bx second resin precursor sheet
10c third resin layer
11a first inorganic insulating layer
11b second inorganic insulating layer
11x inorganic insulating sol
12a first filler
12b second filler
12c third filler
13a first inorganic insulating particles
13b second inorganic insulating particles
14 conductive layer
14x metal foil
15 via conductor
16a first laminate sheet
16b second laminate sheet
17a first neck structure
17b second neck structure
18b projection portion
19a first filling portion
19b second filling portion
19c third filling portion
19d fourth filling portion
O opening
V void
G1 first gap
G2 second gap

1. A structure comprising:
a plurality of first inorganic insulating particles which are connected to each other via first neck structures and have particle size of 3 nm or more and 110 nm or less, and
a resin arranged in gaps among the plurality of first inorganic insulating particles.

2. The structure according to claim 1, wherein
the structure is further provided with a plurality of second inorganic insulating particles which are connected to each other via the first inorganic insulating particles and have a particle size of 0.5 μm or more and 3 μm or less, and
the first inorganic insulating particles and the second inorganic insulating particles are connected to each other via second neck structures.

3. The structure according to claim 2, wherein
the width of the first neck structure is larger than the width of the second neck structure.

4. The structure according to claim 2, wherein
the resin is further arranged in voids surrounded by the plurality of the first inorganic insulating particles and the plurality of the second inorganic insulating particles.

5. A circuit board comprising:
an inorganic insulating layer having a plurality of first inorganic insulating particles which are connected to each other via first neck structures and have a particle size of 3 nm or more and 110 nm or less, and a resin arranged in gaps among the plurality of the first inorganic insulating particles.

6. The circuit board according to claim 5, wherein
the circuit board is further provided with a resin layer which contacts with the inorganic insulating layer, and
the resin is a portion of the resin layer arranged in the gaps.
